(19) United States
(12) Patent Application Publication
(10) Pub. No.: US 2025/0054773 A1
(43) Pub. Date: Feb. 13, 2025

(54) FORMATION METHOD OF PLATING PATTERN AND SEMICONDUCTOR PACKAGE INCLUDING PLATING PATTERN LAYER FORMED THEREBY

(71) Applicant: Samsung Electronics Co., Ltd., Suwon-si (KR)

(72) Inventor: Yuseon HEO, Suwon-si (KR)

(73) Assignee: Samsung Electronics Co., Ltd., Suwon-si (KR)

(21) Appl. No.: 18/431,454

(22) Filed: Feb. 2, 2024

(30) Foreign Application Priority Data
Aug. 11, 2023 (KR) 10-2023-0105483

(51) Int. Cl. H01L 21/48; C23C 18/16; C23C 18/31; C23C 18/48; C23C 28/02; C25D 5/00; C25D 5/02; C25D 7/12; G03F 7/16; G03F 7/30; H01L 23/00; H01L 23/498; H01L 25/065; H01L 25/10; H10B 80/00

(52) U.S. Cl. CPC H01L 21/4857; C23C 18/1653; C23C 18/31; C23C 18/48; C23C 28/021; C23C 28/023; C25D 5/022; C25D 5/605; C25D 7/123; G03F 7/16; G03F 7/30; H01L 23/49822; H01L 23/49827; H01L 24/16; H01L 24/32; H01L 24/73; H01L 25/0657; H01L 25/105; H01L 2224/16227; H01L 2224/32225; H01L 2224/73204; H01L 2225/06506; H01L 2225/0651; H01L 2225/06562; H10B 80/00

(57) ABSTRACT

A method of forming a plating pattern includes forming a first plating layer on a substrate, forming a photosensitive material layer on the first plating layer, patterning the photosensitive material layer to have a trench exposing a portion of the first plating layer, forming a superhydrophobic film on a surface of the photosensitive material layer, forming a second plating layer in the trench by immersing the photosensitive material layer and the first plating layer in a plating solution, and simultaneously removing the superhydrophobic film and the photosensitive material layer.

### CROSS-REFERENCE TO RELATED APPLICATION(S)

This application claims benefit of priority to Korean Patent Application No. 10-2023-0105483 filed on Aug. 11, 2023 in the Korean Intellectual Property Office, the disclosure of which is incorporated herein by reference in its entirety.

### BACKGROUND

The present inventive concepts relate to methods for forming a plating pattern and/or semiconductor packages including a plating pattern layer formed thereby.

In accordance with the trend toward higher performance and miniaturization of electronic devices, signal transmission paths in semiconductor devices are becoming more miniaturized and precise. As a method of forming a refined plating pattern, research into a plating process using a photosensitive material layer as a plating resist is being carried out.

### SUMMARY

Some example embodiments of the present inventive concepts are to provide methods of forming a plating pattern having improved reliability and yield and/or semiconductor packages including a plating pattern layer.

According to an example embodiments, a method of forming a plating pattern includes forming a first plating layer on a substrate, forming a photosensitive material layer on the first plating layer, patterning the photosensitive material layer to have a trench exposing a portion of the first plating layer, forming a superhydrophobic film on a surface of the photosensitive material layer, forming a second plating layer in the trench by immersing the photosensitive material layer and the first plating layer in a plating solution, and simultaneously removing the superhydrophobic film and the photosensitive material layer, wherein a side surface of the second plating layer has a first surface roughness transferred by the plurality of protrusions, and an upper surface of the second plating layer has a second surface roughness, the second surface roughness being lower than the first surface roughness.

According to an example embodiments, a method of forming a plating pattern includes forming a photosensitive material layer on a plating seed layer, patterning the photosensitive material layer to have a trench exposing a portion of the plating seed layer, forming a superhydrophobic film having a plurality of protrusions on the photosensitive material layer, and forming a plating pattern layer in the trench by immersing the photosensitive material layer and the plating seed layer in a plating solution and applying a voltage to the plating seed layer, wherein a temperature of the plating solution is in a range between 40° C. and 100° C.

According to an example embodiments, a method of forming a plating pattern includes forming a photosensitive material layer, patterning the photosensitive material layer to have a trench, forming a superhydrophobic film having a plurality of protrusions on the photosensitive material layer, and forming a plating pattern layer in the trench by immersing the photosensitive material layer in a plating solution, wherein a side surface of the plating pattern layer has a surface roughness transferred by the plurality of protrusions.

According to an example embodiments, a semiconductor package includes a front redistribution structure including front redistribution layers, and first pads and second pads electrically connected to the front redistribution layers, plating pattern layers on at least one of the first pads or the second pads, and a semiconductor chip on the front redistribution structure, the semiconductor chip including connection pads electrically connected to the first pads, wherein a side surface of each of the plating pattern layers has a first surface roughness, and an upper surface of each of the plating pattern layers has a second surface roughness, the second surface roughness being lower than the first surface roughness

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a flowchart illustrating a method of forming a plating pattern according to an example embodiment.

FIGS. 2A to 2E are views illustrating the method of forming a plating pattern of FIG. 1 in process order.

FIGS. 3A to 3E are cross-sectional views of plating patterns formed according to some example embodiments.

FIGS. 4A and 4B are cross-sectional views of substrates each including a plating pattern, formed according to some example embodiments.

FIG. 5 is a cross-sectional view of a semiconductor package including a plating pattern, formed according to an example embodiment.

FIG. 6 is a cross-sectional view of a semiconductor package including a plating pattern, formed according to an example embodiment.

### DETAILED DESCRIPTION

Hereinafter, with reference to the accompanying drawings, some example embodiments of the present inventive concepts will be described as follows. Unless otherwise specified, in this specification, terms such as ‘an upper portion,’ ‘an upper surface,’ ‘a lower portion,’ ‘a lower surface,’ ‘a side surface,’ and the like may be based on the drawings, and in fact, may be changed, depending on directions in which components are arranged.

Additionally, ordinal numbers such as “first,” “second,” “third,” and the like may be used as labels for a specific element, operation, direction, or the like to distinguish various elements, operations, directions, or the like from each other. Terms, not described using “first,” “second,” or the like in the specification may still be referred to as “first” or “second” in the claims. Additionally, terms referenced by a particular ordinal number (e.g., “first” in a particular claim) may be described elsewhere with a different ordinal number (e.g., “second” in the specification or another claim).

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

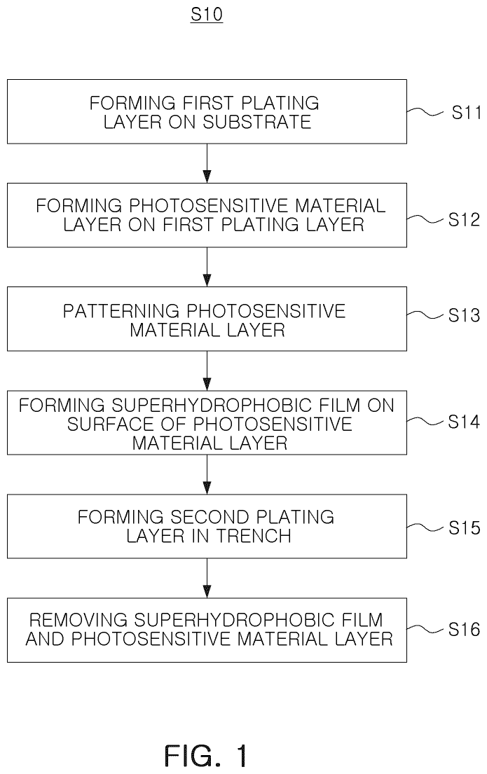

FIG. 1 is a flowchart illustrating a method (S10) of forming a plating pattern according to an example embodiment.

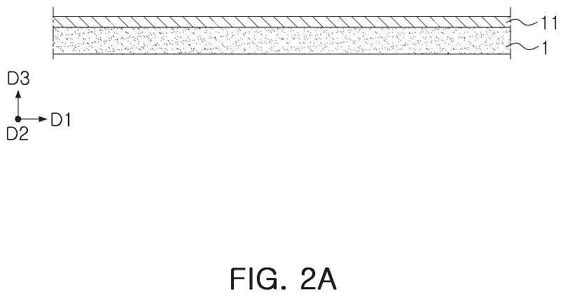

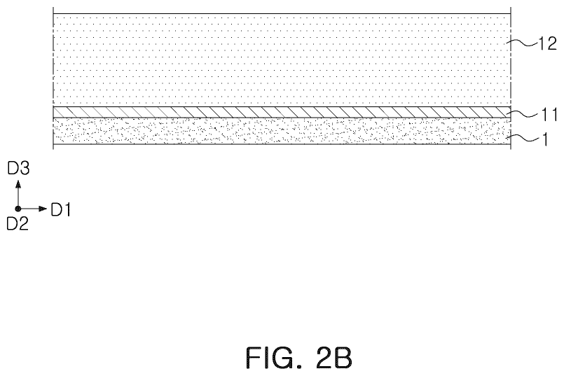

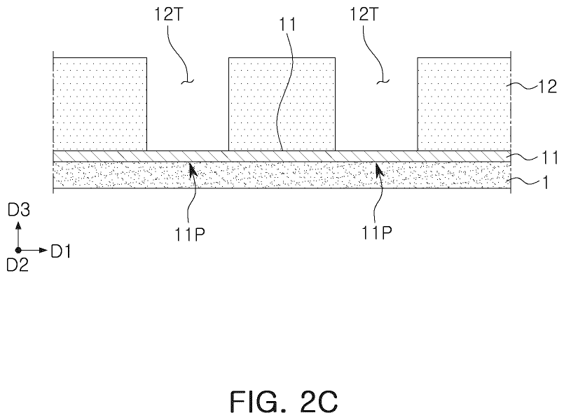

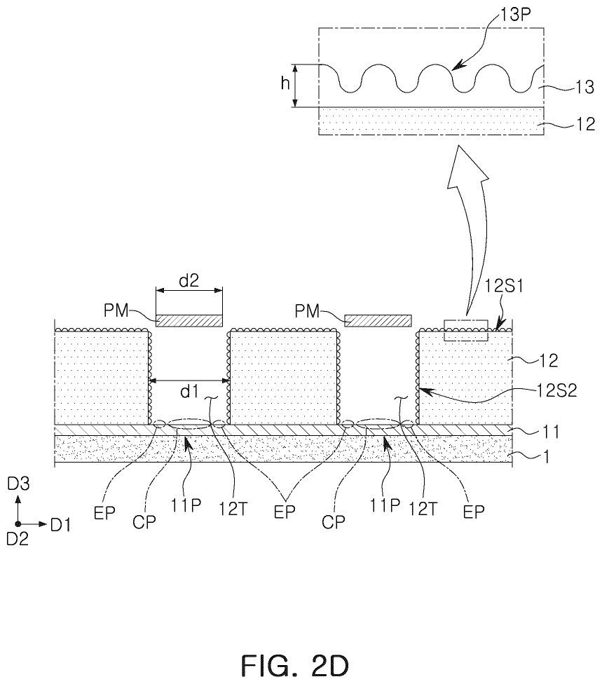

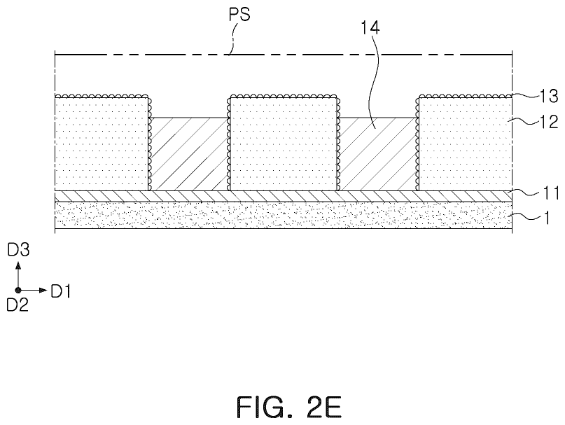

FIGS. 2A to 2E are views illustrating the method (S10) of forming a plating pattern of FIG. 1 in process order.

Referring to FIG. 1, a method of forming a plating pattern (S10) according to an example embodiment may include forming a first plating layer on a substrate (S11), forming a photosensitive material layer on the first plating layer (S12), patterning the photosensitive material layer to have a trench exposing a portion of the first plating layer (S13), forming a superhydrophobic film on a surface of the photosensitive material layer (S14), forming a second plating layer in the trench by immersing the photosensitive material layer and the first plating layer in a plating solution (S15), and simultaneously removing the superhydrophobic film and the photosensitive material layer (S16).

According to some example embodiments, by omitting a high-temperature heat treatment (hard bake) process, a problem to be generated in the high-temperature heat treatment (e.g., occurrence of a crack in a photosensitive material layer, an increase in peeling time (e.g., removal time) of the photosensitive material layer, or the like) may be mitigated or prevented. In this case, the ‘high temperature heat treatment’ refers to heat treatment performed in an atmosphere of approximately 100° C. or higher to mitigate or prevent damage to the photosensitive material layer due to a plating solution. A problem such as leaching of a photosensitive material, weakening of adhesion, or the like due to a plating solution may occur more easily in the plating solution of about 40° C. or higher.

Additionally, according to some example embodiments, process operations may be shortened by omitting pre-treatment such as pickling, descumming, or the like, which is performed after the high-temperature heat treatment.

Additionally, according to some example embodiments, by performing a superhydrophobic film coating process instead of the high-temperature heat treatment and the pre-treatment, leaching of a photosensitive material layer, weakening of adhesion, or the like due to a plating solution may be mitigated or prevented.

Hereinafter, the method of forming a plating pattern (S10) according to an example embodiment will be described in detail.

Referring to FIGS. 1 and 2A, a first plating layer 11 (which may be applied as a ‘plating seed layer’) may be formed on a substrate 1 (S11). The substrate 1 may be formed of an insulating material, for example, a thermosetting resin such as an epoxy resin, a thermoplastic resin such as polyimide, or a prepreg containing an inorganic filler or/and a glass fiber (e.g., a glass fiber, a glass cloth or a glass fabric), an Ajinomoto build-up film (ABF), an FR-4, a photoimageable dielectric (PID), or the like. The first plating layer 11 may be formed by an electroless plating process, but example embodiments are not limited thereto. The first plating layer 11 may include, for example, copper (Cu), aluminum (Al), silver (Ag), gold (Au), nickel (Ni), titanium (Ti), or an alloy thereof. For example, the first plating layer 11 may be formed by an electroless plating process using a plating solution containing a titanium (Ti) ion. When a via hole is formed in the substrate 1, the first plating layer 11 may be formed conformally along an inner wall of the via hole.

Referring to FIGS. 1 and 2B, a photosensitive material layer 12 may be formed on the first plating layer 11 (S12). The photosensitive material layer 12 may include, for example, a resin having a photosensitive functional group. For example, the photosensitive material layer 12 may include a positive photoresist or a negative photoresist. The photosensitive material layer 12 may be formed by applying or laminating a photosensitive resin on the first plating layer 11 and then drying, heating, or pressing the same.

Referring to FIGS. 1 and 2C, the photosensitive material layer 12 may be patterned to have a trench 12T through which a portion 11P of the first plating layer 11 is exposed (S13). The photosensitive material layer 12 may be patterned by a photolithography process including exposure and development. An exposed or unexposed portion of the photosensitive material layer 12 may be removed by a developer such as tetramethylammonium hydroxide (TMAH) or sodium carbonate (Na₂CO₃) to form the trench 12T. The trench 12T may have a depth and expose the portion 11P of the first plating layer 11. The portion 11P of the first plating layer 11 may be referred to as a “plating growth portion 11P.” The trench 12T may be extended in a predetermined pattern shape corresponding to a pattern of a photo mask used for exposure. For example, although FIG. 2C illustrates the trench 12T as a hole penetrating the photosensitive material layer 12, the trench 12T may have a pattern shape extending in directions D1 and D2, although not illustrated in the drawings.

Referring to FIGS. 1 and 2D, a superhydrophobic film 13 may be formed on a surface of the photosensitive material layer 12 (S14). The superhydrophobic film 13 may extend along an upper surface 12S1 of the photosensitive material layer and a side surface 12S2 of the photosensitive material layer 12 that defines a sidewall of the trench 12T. The superhydrophobic film 13 may be formed by a deposition process. For example, the superhydrophobic film 13 may be formed by an atmospheric pressure plasma liquid deposition (APPLD) method in which a liquid precursor is directly applied in an atmospheric pressure plasma zone, but methods according to example embodiments are not limited thereto. The superhydrophobic film 13 may be formed by another deposition process capable of forming a hydrophobic film having a lotus effect on the surface of the photosensitive material layer 12.

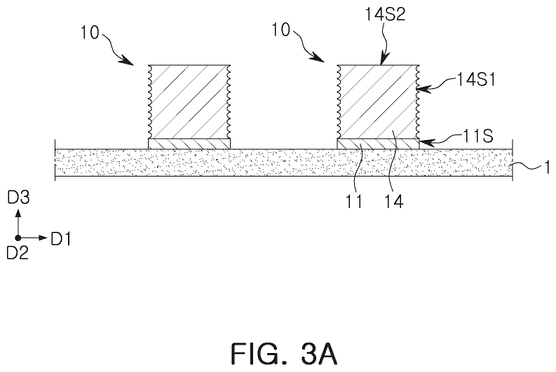

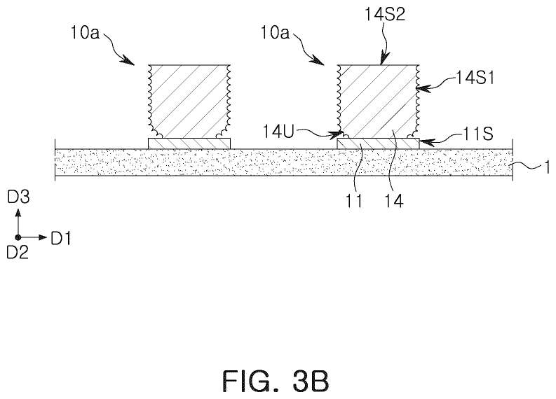

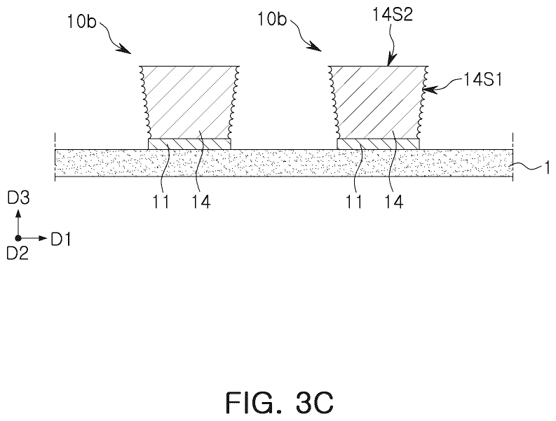

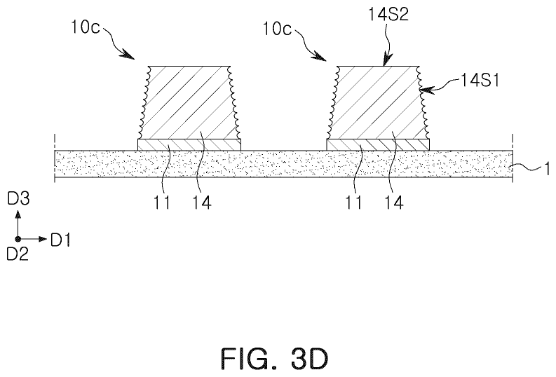

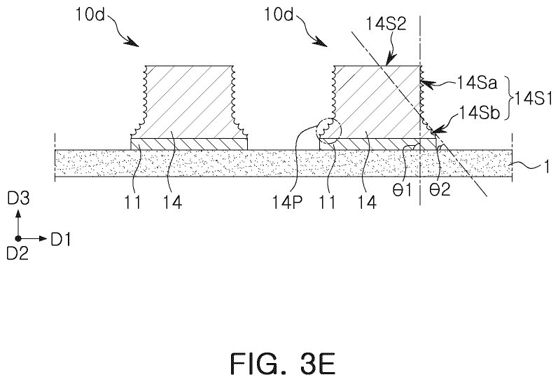

In an example embodiment, a coating mask PM may be disposed on the trench 12T in forming the superhydrophobic film 13. The coating mask PM may block or prevent the superhydrophobic film 13 from being formed on the plating growth portion 11P. In order for the superhydrophobic film 13 to be formed on the side surface 12S2 of the photosensitive material layer 12, a width d2 of the coating mask PM may be smaller than a width d1 of the trench 12T. Due to the coating mask PM, the superhydrophobic film 13 may not be formed at least at a central portion CP of the plating growth portion 11P. In some example embodiments, the superhydrophobic film 13 may be formed on a peripheral portion EP of the plating growth portion 11P (see an embodiment in FIG. 3B).

The superhydrophobic film 13 may include a material that is removed with a developer, which is identical to a developer that is used in removal of the photosensitive material layer 12. For example, the superhydrophobic film 13 may be removed simultaneously with the photosensitive material layer 12 by a developer including, for example, tetramethylammonium hydroxide (TMAH), sodium carbonate (Na₂CO₃), or the like. Therefore, even when the superhydrophobic film 13 is added, the peeling time of the photosensitive material layer 12 may not increase. The superhydrophobic film 13 may include a fluorine-based compound and a (meth)acrylate-based compound, but example embodiments are not limited thereto. The superhydrophobic film 13 may include various materials that may be removed by the developer of the photosensitive material layer 12.

The superhydrophobic film 13 may include a plurality of protrusions 13P attached to the surface of the photosensitive material layer 12. The plurality of protrusions 13P may be formed in a size capable of implementing a lotus effect. A height h of each of the plurality of protrusions 13P may range from about 50 nm to about 100 nm, for example, from about 50 nm to about 90 nm, from about 50 nm to about 80 nm, or from about 60 nm to about 80 nm. When the height h of each of the plurality of protrusions 13P is less than about 50 nm, superhydrophobic properties may be deteriorated. When the height h of each of the plurality of protrusions 13P exceeds about 100 nm, the peeling time of the photosensitive material layer 12 may increase.

Referring to FIGS. 1 and 2E, the photosensitive material layer 12 and the first plating layer 11 may be immersed in a plating solution PS to form a second plating layer 14 (which may be referred to as a ‘plating pattern layer’) in the trench 12T (S15). The second plating layer 14 may be formed by an electroplating process using the first plating layer 11 as a plating seed layer. The second plating layer 14 may be formed on the plating growth portion 11P of the first plating layer 11 to which voltage is applied. The second plating layer 14 may include at least one of copper (Cu), aluminum (Al), silver (Ag), gold (Au), nickel (Ni), titanium (Ti), or an alloy thereof. For example, the plating solution PS may include nickel (Ni) ions, copper (Cu) ions, gold (Au) ions, etc.

Example embodiments may mitigate or prevent damage to the photosensitive material layer 12 due to the plating solution PS by introducing the superhydrophobic film 13. At a temperature of the plating solution PS of about 40° C. or higher, damage to the photosensitive material layer 12 caused by the plating solution PS may increase. The temperature of the plating solution PS applied in some example embodiments may range from about 40° C. or higher to less than about 100° C., for example, about 40° C. or higher to about 90° C., about 40° C. or higher to about 80° C., about 40° C. or higher to about 70° C., about 45° C. or higher to about 70° C., about 45° C. or higher to about 60° C. The temperatures of the plating solution PS applicable to example embodiments are not particularly limited.

The second plating layer 14 may have a surface roughness due to transfer of the protrusions 13P of the superhydrophobic film 13. For example, a side surface of the second plating layer 14 may have a first surface roughness, and an upper surface of the second plating layer 14 may have a second surface roughness, which is lower than the first surface roughness.

Subsequently, the superhydrophobic film 13 and the photosensitive material layer 12 may be removed (S16). The superhydrophobic film 13 and the photosensitive material layer 12 may be simultaneously removed using a developer including, for example, tetramethylammonium hydroxide (TMAH), sodium carbonate (Na₂CO₃), or the like. Therefore, even when the superhydrophobic film 13 is added, the peeling time of the photosensitive material layer 12 may not increase.

Thereafter, the first plating layer 11 may be partially etched to complete a plating pattern 10 illustrated in FIG. 3A. Hereinafter, shapes of the plating pattern 10 according to some example embodiments will be described with reference to FIGS. 3A to 3E.

FIGS. 3A to 3E are cross-sectional views of plating patterns 10, 10a, 10b, 10c, and 10d formed according to some example embodiments.

Referring to FIG. 3A, a plating pattern 10 of an example embodiment may include a first plating layer 11 and a second plating layer 14. For example, the first plating layer 11 may include titanium (Ti) and/or copper (Cu), and the second plating layer 14 may include nickel (Ni), gold (Au), or copper (Cu), but example embodiments are not limited thereto.

The plating pattern 10 may have a surface roughness transferred by a superhydrophobic film 13 during the manufacturing process of FIG. 2E. For example, a side surface 14S1 of the second plating layer 14 may have a surface roughness transferred by the superhydrophobic film 13, and an upper surface 14S2 of the second plating layer 14 may have a surface roughness that is not affected by the transfer of the superhydrophobic film 13. For example, the side surface 14S1 of the second plating layer 14 may have a first surface roughness, and the upper surface 14S2 of the second plating layer 14 may have a second surface roughness, which is lower than the first surface roughness. A side surface 11S of the first plating layer 11 may have a surface roughness that is not affected by the superhydrophobic film 13. For example, the side surface 11S of the first plating layer 11 may have a third surface roughness, which is lower than the first surface roughness.

Referring to FIG. 3B, a plating pattern 10a of an example embodiment may include an undercut region 14U. The undercut region 14U may be formed at a lower edge of a second plating layer 14. The undercut region 14U may be formed by transferring a portion of a superhydrophobic film 13 formed on a peripheral portion EP of a plating growth portion 11P, as illustrated in FIG. 2D. Therefore, the undercut region 14U may have a surface roughness transferred by the superhydrophobic film 13. The undercut region 14U may have a surface roughness, higher than a surface roughness of an upper surface 14S2 of the second plating layer 14 and a surface roughness of a side surface 11S of a first plating layer 11.

Referring to FIG. 3C, a plating pattern 10b in an example embodiment may have a shape of which a width decreases toward a lower portion thereof. For example, a second plating layer 14 may have a side surface 14S1 having a tapered shape such that a width thereof decreases toward a first plating layer 11. The second plating layer 14 may be formed by patterning a photosensitive material layer 12 including a negative photosensitive material (see FIG. 2C). The side surface 14S1 of the second plating layer 14 may have a surface roughness transferred by a superhydrophobic film 13. A width of the first plating layer 11 may correspond to a width of a lower portion of the second plating layer 14. The width of the first plating layer 11 may be smaller than a width of an upper portion of the second plating layer 14.

Referring to FIG. 3D, a plating pattern 10c in an example embodiment may have a shape of which a width decreases toward an upper portion thereof. For example, a second plating layer 14 may have a side surface 14S1 having a tapered shape such that a width thereof increases toward a first plating layer 11. The second plating layer 14 may be formed by patterning a photosensitive material layer 12 including a positive photosensitive material (see FIG. 2C). The side surface 14S1 of the second plating layer 14 may have a surface roughness transferred by a superhydrophobic film 13. A width of the first plating layer 11 may correspond to a width of a lower portion of the second plating layer 14. The width of the first plating layer 11 may be greater than a width of an upper portion of the second plating layer 14.

Referring to FIG. 3E, a plating pattern 10d of an example embodiment may include a lower protrusion 14P. For example, a side surface 14S1 of a second plating layer 14 may include a first portion 14Sa having a first inclination angle θ1 and a second portion 14Sb having a second inclination angle θ2. The second inclination angle θ2 may be smaller than the first inclination angle θ1. The lower protrusion 14P may be formed by an undercut (not illustrated) of a photosensitive material layer 12 generated during a patterning process of the photosensitive material layer 12, as illustrated in FIG. 2C.

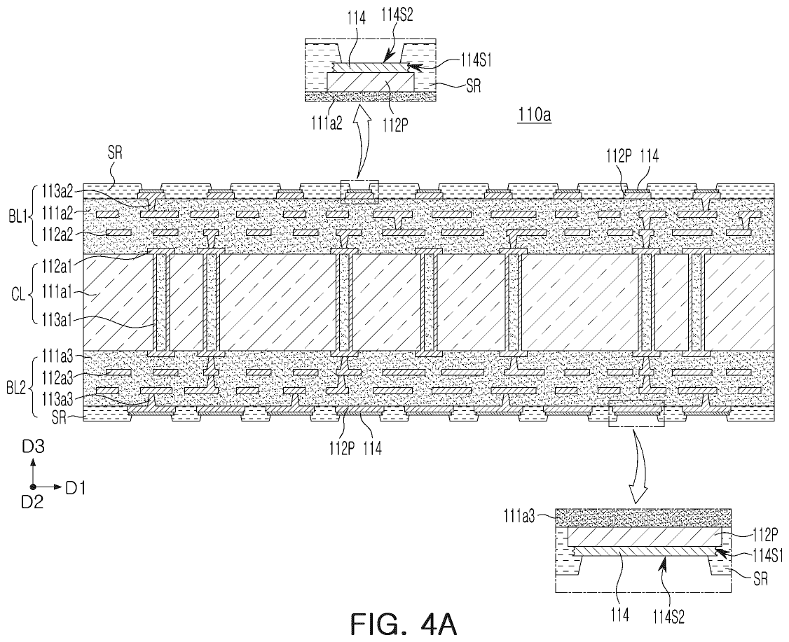

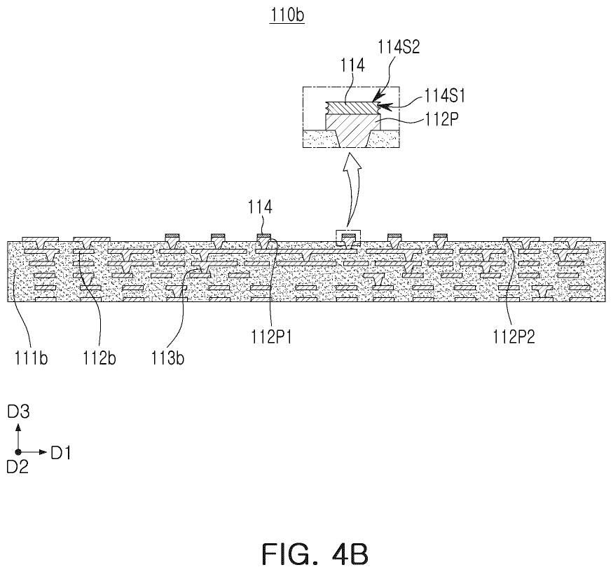

FIGS. 4A and 4B are cross-sectional views of wiring substrates 110a and 110b each including a plating pattern, formed according to some example embodiments.

Referring to FIG. 4A, a wiring substrate 110a of an example embodiment may include a core substrate portion CL, an upper substrate portion BL1, and a lower substrate portion BL2. Depending on example embodiments, at least one of the core substrate portion CL, the upper substrate portion BL1, or the lower substrate portion BL2 may be omitted.

Additionally, the wiring substrate 110a of an example embodiment may further include a surface finishing layer 114 disposed on pads 112P. The surface finishing layer 114 may be a plating pattern formed by a process described with reference to FIGS. 2A to 2E (referred to as a ‘plating pattern layer’). The surface finishing layer 114 may be formed on some or all of upper and lower pads 112P. The surface finishing layer 114 may be formed by an electroplating process using the pads 112P or a barrier layer (not illustrated) below the pads 112P as a plating seed layer. The pads 112P may include copper (Cu) or an alloy thereof, and the barrier layer (not illustrated) may include titanium (Ti) or an alloy thereof, but example embodiments are not limited thereto.

The surface finishing layer 114 may include nickel (Ni) and/or gold (Au). The surface finishing layer 114 may have a surface roughness transferred by a superhydrophobic film 13 during the manufacturing process of FIG. 2E. For example, a side surface 114S1 of the surface finishing layer 114 may have a surface roughness transferred by the superhydrophobic film 13, and an upper surface 114S2 of the surface finishing layer 114 may have a surface roughness that is not affected by the superhydrophobic film 13. For example, the side surface 114S1 of the surface finishing layer 114 may have a first surface roughness, and the upper surface 114S2 of the surface finishing layer 114 may have a second surface roughness, which is lower than the first surface roughness. Additionally, the side surface 114S1 of the surface finishing layer 114 may have a surface roughness, which is higher than that of a side surface of the pads 112P, but example embodiments are not limited thereto. Depending on example embodiments, side surfaces of the pads 112P and wiring patterns 112a1, 112a2, and 112a3, which will be described later, each may also have a surface roughness formed during the manufacturing process of FIG. 2E.

The core substrate portion CL may include core insulating layer 111a1, core wiring patterns 112a1 disposed on both surfaces (upper and lower surfaces) of the core insulating layer 111a1, and core vias 113a1 passing through the core insulating layer 111a1 and connecting the core wiring patterns 112a1 to each other. The core substrate portion CL may have a multilayer core substrate structure in which a plurality of core insulating layers 111a1 are stacked according to a design.

The core insulating layer 111a1 may improve rigidity of the substrate, and may suppress warpage of the substrate. A thickness of the core insulating layer 111a1 may be greater than a thickness of an upper build-up insulating layer 111a2 and a thickness of a lower build-up insulating layer 111a3. The core insulating layer 111a1 may include an insulating material, for example, a thermosetting resin such as an epoxy resin, a thermoplastic resin such as polyimide, or a prepreg containing an inorganic filler or/and a glass fiber, ABF, FR-4, or the like. The core insulating layer 111a1 may be formed using, for example, a copper clad laminate (CCL), an unclad copper clad laminate (unclad CCL), a glass substrate, a ceramic substrate, or the like.

The core wiring patterns 112a1 include, for example, at least one metal of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or an alloy containing two or more metals. The core wiring patterns 112a1 may be electrically connected to at least one of upper wiring patterns 112a2 or lower wiring patterns 112a3.

The core via 113a1 may be a structure in which a via hole penetrating the core insulating layer 111a1 is completely filled with a conductive material, or a conductive material is formed conformally along a wall of the via hole. When the core via 113a1 is formed conformally, an inner space of the core vias 113a1 may be filled with an insulating material such as an epoxy resin or the like.

The upper substrate portion BL1 may include an upper build-up insulating layer 111a2, upper wiring patterns 112a2 disposed on the upper build-up insulating layer 111a2, and upper wiring vias 113a2 passing through the upper build-up insulating layer 111a2 and connecting the upper wiring patterns 112a2 and the core wiring patterns 112a1.

The upper build-up insulating layer 111a2 may have a structure in which a plurality of insulating layers formed of an insulating material are stacked. The plurality of insulating layers may be integrated such that a boundary therebetween is not clear. The insulating material may include, for example, a thermosetting resin such as an epoxy resin, a thermoplastic resin such as polyimide, or a prepreg containing an inorganic filler or/and a glass fiber, ABF, FR-4, a photosensitive resin, or the like.

The upper wiring patterns 112a2 may include, for example, at least one metal of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or an alloy containing two or more metals.

The upper wiring vias 113a2 may pass through at least a portion of the upper build-up insulating layer 111a2, and may connect upper wiring patterns 112a2 located in different layers or the upper wiring patterns 112a2 and the core wiring patterns 112a1. The upper wiring vias 113a2 may include a conductive material similar to the upper wiring patterns 112a2. The upper wiring vias 113a2 each may have a filled via shape in which a via hole is filled with a metal material or a conformal via shape in which a metal material is formed along an inner wall of the via hole.

The lower substrate portion BL2 may include a lower build-up insulating layer 111a3, lower wiring patterns 112a3 disposed on the lower build-up insulating layer 111a3, and lower wiring vias 113a3 passing through the lower build-up insulating layer 111a3 and connecting the lower wiring patterns 112a3 and the core wiring patterns 112a1. Because the lower substrate portion BL2 has similar characteristics to the upper substrate portion BL1, descriptions of the lower build-up insulating layer 111a3, lower wiring patterns 112a3, and lower wiring vias 113a3 may be omitted. The lower substrate portion BL2 may have a symmetrical structure with the upper substrate portion BL1 with respect to the core substrate portion CL. For example, both the lower wiring vias 113a3 and the upper wiring vias 113a2 may have a tapered shape of which a width decreases toward the core substrate portion CL. Therefore, the lower wiring vias 113a3 and the upper wiring vias 113a2 may have a tapered shape in opposite directions.

The wiring substrate 110a of an example embodiment may further include a protective layer SR. The protective layer SR may be disposed on the upper substrate portion BL1 and the lower substrate portion BL2, respectively. The protective layer SR may have an opening exposing at least a portion of the pads 112P disposed on upper and lower surfaces of the wiring substrate 110a. The protective layer SR may include one of the above-mentioned insulating materials. For example, the protective layer SR may be formed using a solder resist. Depending on example embodiments, the protective layer SR may be formed in a non-solder mask defined (NSMD) structure completely exposing the pads 112P.

Referring to FIG. 4B, a wiring substrate 110b of an example embodiment may be a redistribution structure stacked in one direction. The wiring substrate 110b may include an insulating layer 111b, redistribution patterns 112b, and redistribution vias 113b. Additionally, the wiring substrate 110b may further include a surface finishing layer 114 disposed on pads 112P1 and 112P2. The surface finishing layer 114 may be a plating pattern formed by the process described with reference to FIGS. 2A to 2E (referred to as a ‘plating pattern layer’). The surface finishing layer 114 may be formed by an electroplating process using the pads 112P1 and 112P2 or a barrier layer (not illustrated) below the pads 112P1 and 112P2 as a plating seed layer. Depending on example embodiments, the surface finishing layer 114 may be formed only on first pads 112P1 to be bonded to a solder in a subsequent process, and may not be formed on second pads 112P2, but example embodiments are not limited thereto.

The surface finishing layer 114 may include nickel (Ni) and/or gold (Au). A side surface 114S1 of the surface finishing layer 114 may have a surface roughness transferred by a superhydrophobic film 13, and an upper surface 114S2 of the surface finishing layer 114 may have a surface roughness that is not affected by the superhydrophobic film 13. For example, the side surface 114S1 of the surface finishing layer 114 may have a first surface roughness, and the upper surface 114S2 of the surface finishing layer 114 may have a second surface roughness, which is lower than the first surface roughness. Additionally, the side surface 114S1 of the surface finishing layer 114 may have a surface roughness, which is higher than that of a side surface of each of the first and second pads 112P1 and 112P2, but example embodiments are not limited thereto. Depending on example embodiments, side surfaces of the first and second pads 112P1 and 112P2 and the redistribution patterns 112b each may also have a surface roughness formed during the manufacturing process of FIG. 2E.

The insulating layer 111b may include a plurality of layers stacked in a vertical direction (D3 direction). Depending on a process, boundaries between multiple layers may be unclear. The insulating layer 111b may include an insulating resin such as a prepreg, ABF, FR-4, BT, PID, or the like. For example, the insulating layer 111b may include a photosensitive resin such as PID.

The redistribution patterns 112b may include, for example, a metal material including copper (Cu), aluminum (Al), silver (Ag), tin (Sn), gold (Au), nickel (Ni), lead (Pb), titanium (Ti), or an alloy thereof. The redistribution patterns 112b may include a ground pattern, a power pattern, and a signal pattern, depending on a design. In this case, the signal pattern may provide a transmission path for various signals, for example, a data signal or the like, excluding the ground pattern, the power pattern, or the like.

The redistribution vias 113b may pass through a portion of the insulating layer 111b, and may be electrically connected to the redistribution patterns 112b. For example, the redistribution vias 113b may interconnect redistribution patterns 112b on different levels. The redistribution vias 113b may include a signal via, a ground via, and a power via. The redistribution vias 113b may include, for example, copper (Cu), aluminum (Al), silver (Ag), tin (Sn), gold (Au), nickel (Ni), lead (Pb), titanium (Ti), or an alloy thereof. The redistribution vias 113b may be filled vias in each of which a via hole is filled with a metal material or conformal vias in each of which a metal material extends along an inner wall of the via hole.

As such, wiring substrates (e.g., 110a and 110b) to which a method (S10) of forming a plating pattern according to an example embodiment is applied may include a plating pattern having a surface roughness formed in the process of FIG. 2E. The wiring substrates 110a and 110b illustrated in FIGS. 4A and 4B are illustrated as examples, and types of substrates manufactured by applying methods for forming a plating pattern according to example embodiments are not limited thereto.

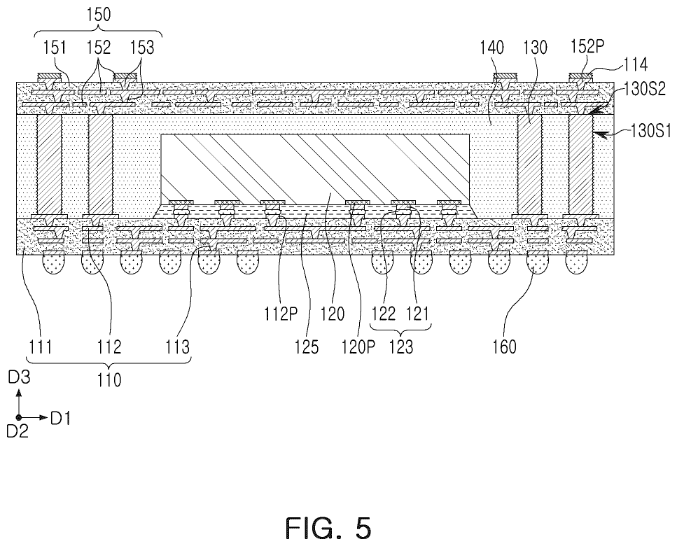

FIG. 5 is a cross-sectional view of a semiconductor package 100 including a plating pattern, formed according to an example embodiment.

Referring to FIG. 5, a semiconductor package 100 of an example embodiment may include a front redistribution structure 110, a semiconductor chip 120, a through-via 130, and an encapsulant 140. Depending on an example embodiment, the semiconductor package 100 may further include a rear redistribution structure 150.

The through-via 130 may pass through the encapsulant 140 to electrically connect front redistribution layers 112 and rear redistribution layers 152. The through-via 130 may be a plating pattern formed by the process described with reference to FIGS. 2A to 2E (referred to as a ‘plating pattern layer’). The through-via 130 may be formed by an electroplating process using a metal seed layer (not illustrated) containing titanium (Ti), copper (Cu), or the like. The through-via 130 may include copper (Cu), but example embodiments are not limited thereto. A side surface 130S1 of the through-via 130 may have a surface roughness transferred by a superhydrophobic film 13, and an upper surface 130S2 of the through-via 130 may have a surface roughness that is not affected by the superhydrophobic film 13. For example, the side surface 130S1 of the through-via 130 may have a first surface roughness, and the upper surface 130S2 of the through-via 130 may have a second surface roughness, which is lower than the first surface roughness. Depending on an example embodiment, the side surface 130S1 of the through-via 130 may have a greater surface roughness than a side surface of a pad portion 112P.

The front redistribution structure 110 may include an insulating layer 111, front redistribution layers 112, and front redistribution vias 113. The front redistribution structure 110 may have a structure similar to the substrate 110b illustrated in FIG. 4B, but example embodiments are not limited thereto. The front redistribution structure 110 may be the substrate 110a illustrated in FIG. 4A or a package substrate having a type different from those of FIGS. 4A and 4B. The insulating layer 111 may include, for example, a photosensitive resin such as a photoimageable dielectric (PID), but example embodiments are not limited thereto. The front redistribution layers 112 may further include a pad portion 112P. Depending on an example embodiment, a surface finishing layer (not illustrated) containing nickel (Ni), gold (Au), or an alloy thereof may be formed on the pad portion 112P. For example, as illustrated in FIG. 4B, a surface finishing layer (‘114’ in FIG. 4B) may be disposed between the pad portion 112P of the front redistribution structure 110 and a connection bump 123. The front redistribution layers 112 and the front redistribution vias 113 may include, for example, copper (Cu), aluminum (Al), silver (Ag), tin (Sn), gold (Au), nickel (Ni), lead (Pb), titanium (Ti), or an alloy thereof. Depending on an example embodiment, side surfaces of the front redistribution layers 112 may also have a surface roughness formed during the manufacturing process of FIG. 2E.

The semiconductor chip 120 may include a connection pad 120P electrically connected to the front redistribution layers 112. The semiconductor chip 120 may be a memory chip including a logic chip such as a central processor (CPU), a graphics processor (GPU), a field programmable gate array (FPGA), an application processor (AP), a digital signal processor, a cryptographic processor, a microprocessor, a microcontroller, an analog-digital converter, an application specific integrated circuit (ASIC), or the like, a volatile memories such as a dynamic RAM (DRAM), a static RAM (SRAM), or the like, or a non-volatile memory such as a phase change RAM (PRAM), a magnetic RAM (MRAM), and a resistive RAM (RRAM), a flash memory, or the like.

The semiconductor chip 120 may be electrically connected to the front redistribution layer 112 through the connection bump 123. The connection bump 123 may be disposed between the pad portion 112P and the connection pad 120P. For example, the connection bump 123 may include a pillar portion 121 contacting the connection pad 120P and a solder portion 122 contacting the pad portion 112P. An underfill layer 125 may be disposed between the semiconductor chip 120 and the front redistribution structure 110. The underfill layer 125 may include an insulating resin such as epoxy resin, and may protect the connection bumps 123 physically and electrically. The underfill layer 125 may have a capillary underfill (CUF) structure, but example embodiments not limited thereto. Depending on an example embodiment, the underfill layer 125 may have a molded underfill (MUF) structure integrated with the encapsulant 140.

The sealant 140 may seal the semiconductor chip 120 and the through-via 130. The encapsulant 140 may include, for example, an insulating resin such as a prepreg, ABF, FR-4, BT, or an epoxy molding compound (EMC).

The rear redistribution structure 150 may include a rear insulating layer 151, rear redistribution layers 152, and rear redistribution vias 153. Because the rear redistribution structure 150 has similar characteristics to the front redistribution structure 110, descriptions of the rear insulating layer 151, the rear redistribution layers 152, and the rear redistribution vias 153 may be omitted. Depending on an example embodiment, the surface finishing layer 114 of FIGS. 4A and 4B may be formed on pads 152P of the rear redistribution structure 150.

Depending on an example embodiment, solder bumps 160 may be disposed below the front redistribution structure 110. The semiconductor package 100 may be connected to an external device such as a module substrate, a main board, or the like through the solder bumps 160. The solder bumps 160 may include a low melting point metal, for example, tin (Sn) or an alloy containing tin (Sn) (Sn—Ag—Cu).

As such, a semiconductor package (e.g., 100) to which a method (S10) of forming a plating pattern according to some example embodiment is applied may include a plating pattern (e.g., through-via 130) having a surface roughness formed in the process of FIG. 2E. The semiconductor package 100 illustrated in FIG. 5 is illustrated as an example, and types of semiconductor packages manufactured by applying methods for forming a plating pattern according to example embodiments are not limited thereto.

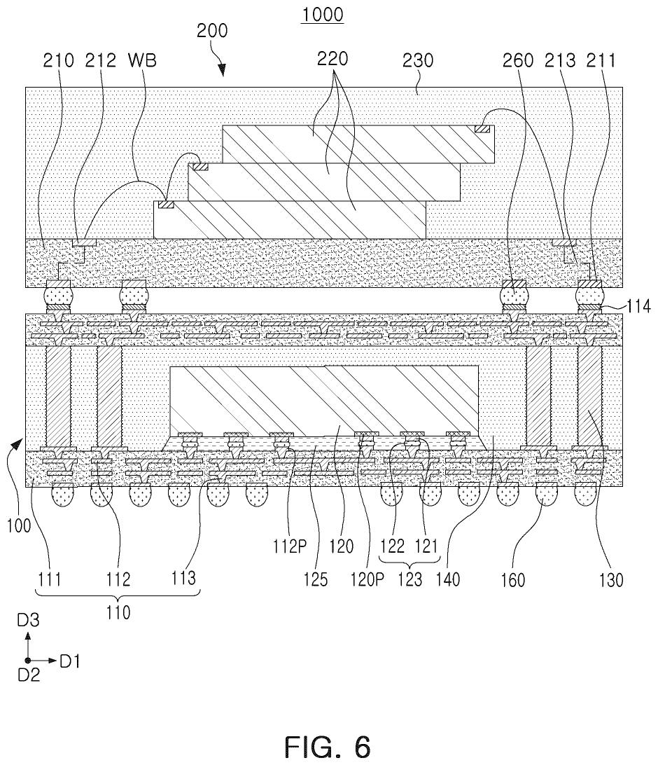

FIG. 6 is a cross-sectional view of a semiconductor package 1000 including a plating pattern, formed according to an example embodiment.

Referring to FIG. 6, a semiconductor package 1000 of an example embodiment may include a first package 100 and a second package 200. The first package 100 can be understood as having the same or similar characteristics as the semiconductor package 100 illustrated in FIG. 5.

The second package 200 may include a wiring substrate 210, a second semiconductor chip 220, and a second encapsulant 230. The wiring substrate 210 may include a lower pad 211, an upper pad 212, and a wiring circuit 213.

The second semiconductor chip 220 may be mounted on the wiring substrate 210 using a wire bonding method or a flip chip bonding method. For example, a plurality of second semiconductor chips 220 may be stacked on the wiring substrate 210 in a vertical direction, and may be electrically connected to the upper pad 212 of the wiring substrate 210 by a bonding wire (WB). The second semiconductor chip 220 may be a chip, which is different from a first semiconductor chip 120. For example, the second semiconductor chip 220 may include a memory chip, and the first semiconductor chip 120 may include an AP chip.

The second encapsulant 230 may include the same or similar material as an encapsulant 140 of the first package 100. The second package 200 may be physically and electrically connected to the first package 100 by a solder bump 260. The solder bump 260 may be electrically connected to the wiring circuit 213 in the wiring substrate 210 through the lower pad 211 of the wiring substrate 210. The solder bump 260 may include a low melting point metal, for example, tin (Sn) or an alloy containing tin (Sn). Depending on an example embodiment, the surface finishing layer 114 of FIGS. 4A and 4B may be formed between the solder bump 260 and pads 152P of a rear redistribution structure 150.

As such, a semiconductor package (e.g., 1000) to which a method (S10) of forming a plating pattern according to an example embodiment is applied may include a plating pattern (e.g., through-via 130) having a surface roughness formed in the process of FIG. 2E. The semiconductor package 1000 illustrated in FIG. 6 is illustrated as an example, and types of semiconductor packages manufactured by applying methods for forming a plating pattern according to example embodiments are not limited thereto.

According to example embodiments, methods of forming plating patterns having improved reliability and yield and/or methods for forming semiconductor packages including such plating patterns may be provided by making a patterned photosensitive material layer superhydrophobic.

Various advantages and effects of the present inventive concepts are not limited to the above-described content, and may be more easily understood through description of specific example embodiments.

While some example embodiments have been illustrated and described above, it will be apparent to those skilled in the art that modifications and variations could be made without departing from the scope of the present inventive concepts as defined by the appended claims.

1. A method of forming a plating pattern, comprising:
forming a first plating layer on a substrate;
forming a photosensitive material layer on the first plating layer;
patterning the photosensitive material layer to have a trench exposing a portion of the first plating layer;
forming a superhydrophobic film having a plurality of protrusions on a surface of the photosensitive material layer;
forming a second plating layer in the trench by immersing the photosensitive material layer and the first plating layer in a plating solution; and
simultaneously removing the superhydrophobic film and the photosensitive material layer,
wherein a side surface of the second plating layer has a first surface roughness transferred by the plurality of protrusions, and
an upper surface of the second plating layer has a second surface roughness, the second surface roughness being lower than the first surface roughness.

2. The method of claim 1, wherein the superhydrophobic film extends along an upper surface and a side surface of the photosensitive material layer.

3. The method of claim 2, wherein
the forming a superhydrophobic film includes disposing a coating mask on the trench, and
a width of the coating mask is smaller than a width of the trench.

4. The method of claim 2, wherein the superhydrophobic film is not formed at least at a central portion of the portion of the first plating layer.

5. The method of claim 1, wherein the superhydrophobic film comprises a material that is removable with a developer used to remove the photosensitive material layer.

6. The method of claim 5, wherein the superhydrophobic film comprises a fluorine-based compound and a (meth)acrylate-based compound.

7. The method of claim 5, wherein the superhydrophobic film and the photosensitive material layer are simultaneously removed by a developer comprising tetramethylammonium hydroxide (TMAH) or sodium carbonate (Na₂CO₃).

8. The method of claim 1, wherein heights of the plurality of protrusions range from 50 nm to 100 nm.

9. The method of claim 1, wherein a temperature of the plating solution is in a range between 40° C. and 100° C.

10. The method of claim 1, wherein the second plating layer is formed by an electroplating process.

11. The method of claim 1, wherein the second plating layer comprises at least one of nickel (Ni), copper (Cu), gold (Au), or an alloy thereof.

12. The method of claim 1, wherein the first plating layer is formed by an electroless plating process.

13. The method of claim 1, wherein the first plating layer comprises at least one of titanium (Ti) or an alloy thereof.

14. The method of claim 1, wherein the photosensitive material layer is patterned by a photo lithography process.

15. The method of claim 1, wherein the photosensitive material layer comprises a positive photoresist or a negative photoresist.

16. A method of forming a plating pattern, comprising:
forming a photosensitive material layer on a plating seed layer;
patterning the photosensitive material layer to have a trench exposing a portion of the plating seed layer;
forming a superhydrophobic film having a plurality of protrusions on the photosensitive material layer; and
forming a plating pattern layer in the trench by immersing the photosensitive material layer and the plating seed layer in a plating solution and applying a voltage to the plating seed layer,
wherein a temperature of the plating solution is in a range between 40° C. and 100° C.

17. The method of claim 16, wherein the plating solution comprises a nickel (Ni) ion, a copper (Cu) ion, or a gold (Au) ion.

18. The method of claim 16, wherein the forming a superhydrophobic film forms the superhydrophobic film to extend along an upper surface of the photosensitive material layer and a side surface of the photosensitive material layer.

19. The method of claim 16, further comprising:
simultaneously removing the photosensitive material layer and the superhydrophobic film, after the forming a plating pattern layer.

20. A method of forming a plating pattern, comprising:
forming a photosensitive material layer;
patterning the photosensitive material layer to have a trench;
forming a superhydrophobic film having a plurality of protrusions on the photosensitive material layer; and
forming a plating pattern layer in the trench by immersing the photosensitive material layer in a plating solution,
wherein a side surface of the plating pattern layer has a surface roughness transferred by the plurality of protrusions.

21.-28. (canceled)
